(19) United States
(12) Patent Application Publication
(10) Pub. No.: US 2012/0309182 A1
(43) Pub. Date: Dec. 6, 2012

(54) Method of Forming Sidewall Spacers Having Different Widths Using a Non-Conformal Deposition Process

(75) Inventors: Stefan Flachowsky, Dresden (DE); Jan Hoentschel, Dresden (DE); Peter Javorka, Radeburg (DE)

(73) Assignee: GLOBALFOUNDRIES INC., Grand Cayman (KY)

(21) Appl. No.: 13/118,826

(22) Filed: May 31, 2011

(51) Int. Cl. H01L 21/3205; B82Y 40/00

(52) U.S. Cl. 438/587; 438/595; 977/888; 257/E21.19

(57) ABSTRACT

Disclosed herein is a method of forming sidewall spacers for a semiconductor device. In one example, the method comprises forming a gate electrode structure above a semiconducting substrate. performing a non-conformal deposition process to deposit a layer of spacer material above the gate electrode structure and performing an anisotropic etching process on the layer of spacer material to define a first sidewall spacer proximate a first side of the gate electrode structure and a second sidewall spacer proximate a second side of the gate electrode structure, wherein the first and second sidewall spacers have different widths.

### BACKGROUND OF THE INVENTION

1. Field of the Invention

Generally, the present disclosure relates to the manufacturing of sophisticated semiconductor devices, and, more specifically, to a method of forming sidewall spacers for gate electrode structures using a non-conformal deposition process.

2. Description of the Related Art

The fabrication of advanced integrated circuits, such as CPUs, storage devices, ASICs (application specific integrated circuits) and the like, requires a large number of circuit elements to be formed on a given chip area according to a specified circuit layout, wherein field effect transistors represent one important type of circuit element that substantially determines performance of the integrated circuits. Generally, a plurality of process technologies are currently practiced, wherein, for many types of complex circuitry, including field effect transistors, MOS technology is currently one of the most promising approaches due to the superior characteristics in view of operating speed and/or power consumption and/or cost efficiency. During the fabrication of complex integrated circuits using, for instance, MOS technology, millions of transistors, e.g., N-channel transistors (NMOS) and/or P-channel transistors (PMOS), are formed on a substrate including a crystalline semiconductor layer. A field effect transistor, irrespective of whether an N-channel transistor or a P-channel transistor is considered, typically comprises so-called PN junctions that are formed by an interface of highly doped regions, referred to as drain and source regions, with a slightly doped or non-doped region, such as a channel region, disposed adjacent to the highly doped regions.

In a field effect transistor, the conductivity of the channel region, i.e., the drive current capability of the conductive channel, is controlled by a gate electrode formed adjacent to the channel region and separated therefrom by a thin insulating layer. The conductivity of the channel region, upon formation of a conductive channel due to the application of an appropriate control voltage to the gate electrode, depends upon a variety of factors, such as the dopant concentration, the mobility of the charge carriers and, for a given extension of the channel region in the transistor width direction, on the distance between the source and drain regions, which is also referred to as channel length. Hence, in combination with the capability of rapidly creating a conductive channel below the insulating layer upon application of the control voltage to the gate electrode, the conductivity of the channel region substantially affects the performance of MOS transistors. Thus, as the speed of creating the channel, which depends on, among other things, the conductivity of the gate electrode, and the channel resistivity substantially determine the transistor characteristics, the scaling of the channel length, and associated therewith the reduction of channel resistivity and reduction of gate resistivity, is a dominant design criterion for accomplishing an increase in the operating speed of the integrated circuits.

The circuit and device structure requirements for input and output terminals of amplifying devices (analog devices) and switching devices (digital transistors) are typically different in most applications, particularly in analog and mixed-signal applications. Thus, the use of symmetric MOSFET devices in those applications may be less than desirable and the may involve design compromises and or reduced performance relative to using asymmetric devices to manufacture integrated circuits for such applications. An asymmetric MOSFET can be generally described as having a laterally non-uniform channel profile with or without different profiles for the source region and the drain region. In a conventional symmetric MOSFET device, the channel region is typically uniformly doped and it shuts down (becomes essentially non-conductive) over its entire uniformly-doped channel when the voltage applied to the gate electrode is below the threshold voltage of the device.

Some prior art designs for asymmetric transistors attempt to control the amount by which the source region and/or drain region extend under the gate electrode. Since the carriers are injected from the source region into the channel, it is important to have a good connection between the highly-doped source region and the channel region of the device. This connection can be accomplished in a variety of ways, e.g., a smaller spacer can be provided on the source side of the gate electrode as compared to the drain side of the gate electrode, and/or the dopant dose used to form both the source region and the drain region can be increased which will lead to increased diffusion of the source region and the drain region under the gate electrode during the activation anneal process. Unfortunately, these extensions of the source region and the drain region under the gate electrode creates parasitic capacitances that reduce the switching speed of the device. In some cases, attempts have been made to create asymmetric devices using different implant doses for the source region and the drain region, but such efforts typically involve performing separate masking and implanting processes for the source region and the drain region, which add to the cost and complexity of the finished device.

The present disclosure is directed to various methods and resulting devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to the manufacturing of sophisticated semiconductor devices, and, more specifically, to a method of forming sidewall spacers of differing widths for gate electrode structures using a non-conformal deposition process. In one example, the method includes forming a gate electrode structure above a semiconducting substrate. performing a non-conformal deposition process to deposit a layer of spacer material above the gate electrode structure and performing an anisotropic etching process on the layer of spacer material to define a first sidewall spacer proximate a first side of the gate electrode structure and a second sidewall spacer proximate a second side of the gate electrode structure, wherein the first and second sidewall spacers have different widths.

A further illustrative method disclosed herein includes forming at least neighboring first, second and third gate electrode structures above a semiconducting substrate, wherein the second gate electrode structure is positioned laterally between the first and third gate electrode structures, and wherein the space between the nearest sidewalls of the second and third gate electrode structures is at least 100 nm greater than the space between the nearest sidewalls of the first and second gate electrode structures, performing a non-conformal deposition process to deposit a layer of spacer material above at least the first, second and third gate electrode structures, and performing an anisotropic etching process on the layer of spacer material to define a first sidewall spacer proximate a first side of the second gate electrode structure and a second sidewall spacer proximate a second side of the second gate electrode structure, wherein the first and second sidewall spacers have different widths. In even further embodiments, the space between the nearest sidewalls of the second and third gate electrode structures is at least 300 nm, while the space between the nearest sidewalls of the first and second gate electrode structures is 150 nm or less.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1E depicts one illustrative example of a method of making a sidewall spacers having different widths and a semiconductor device comprising such spacers.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure is directed to techniques that may be employed in forming sidewall spacers having different widths for gate electrode structures by performing a non-conformal deposition process. As will be readily apparent to those skilled in the art upon a complete reading of the present application, the present method is applicable to a variety of technologies, e.g., NMOS, PMOS, CMOS, etc., and is readily applicable to a variety of devices, including, but not limited to, logic devices, memory devices, etc.

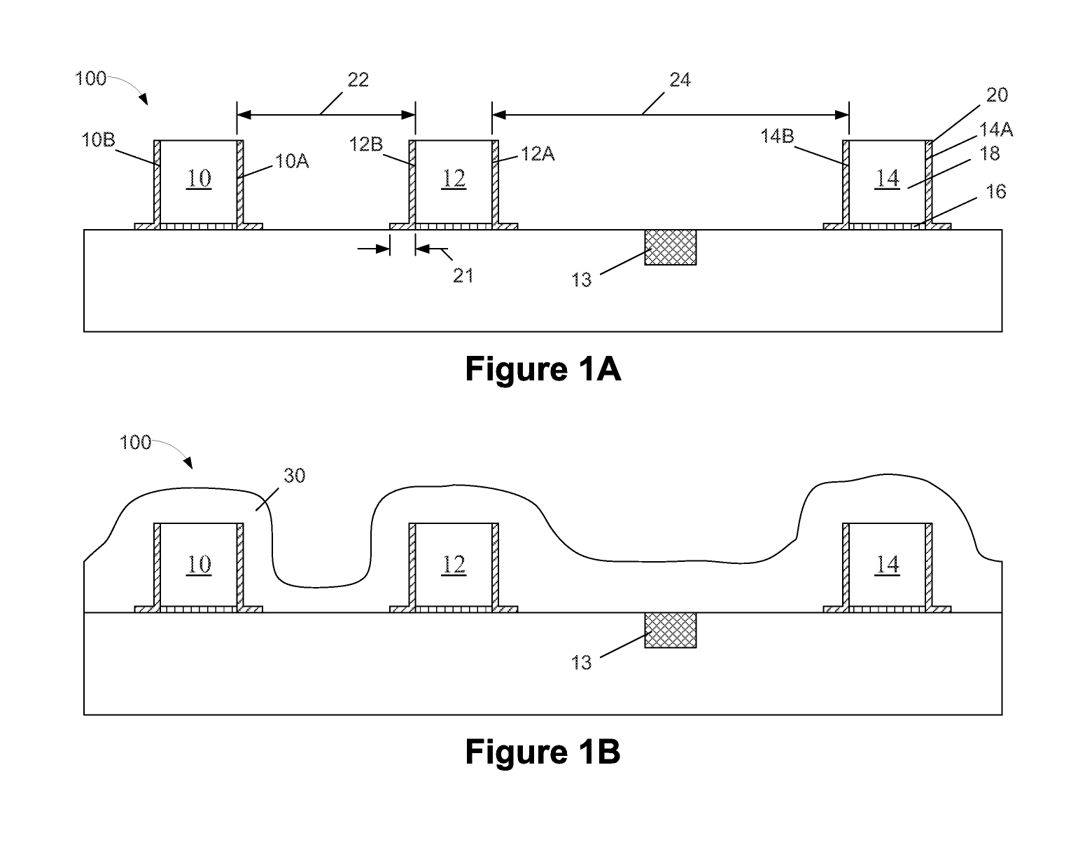

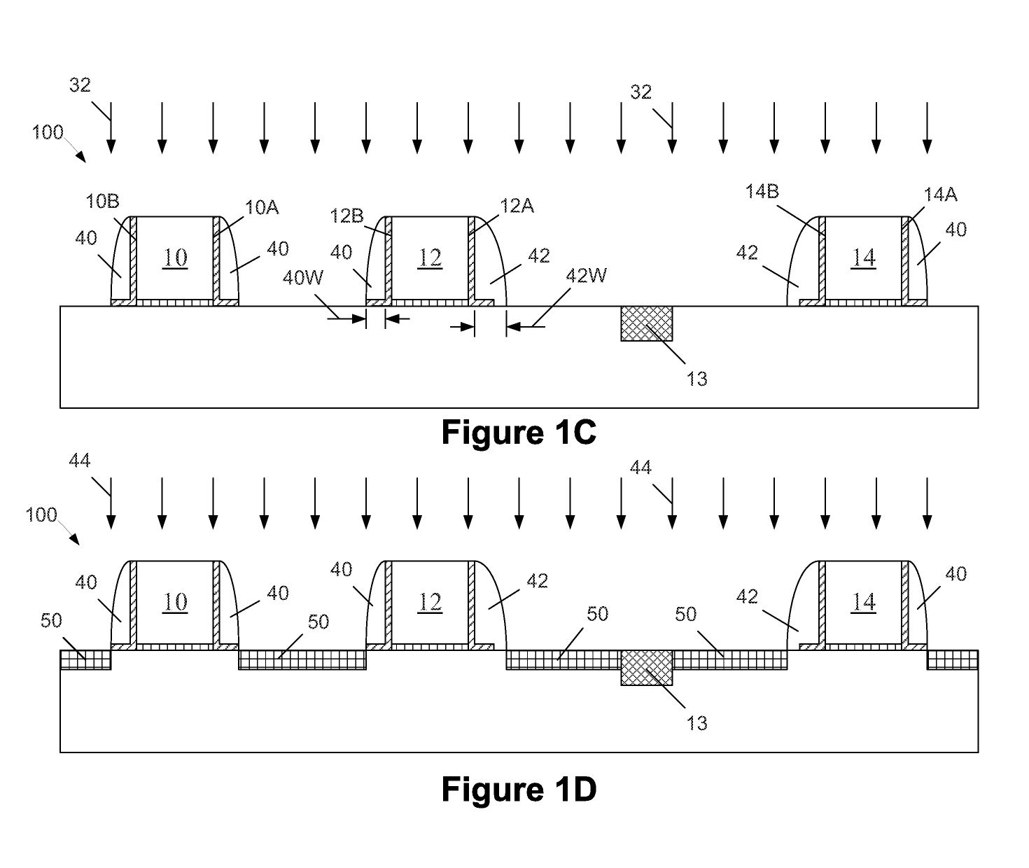

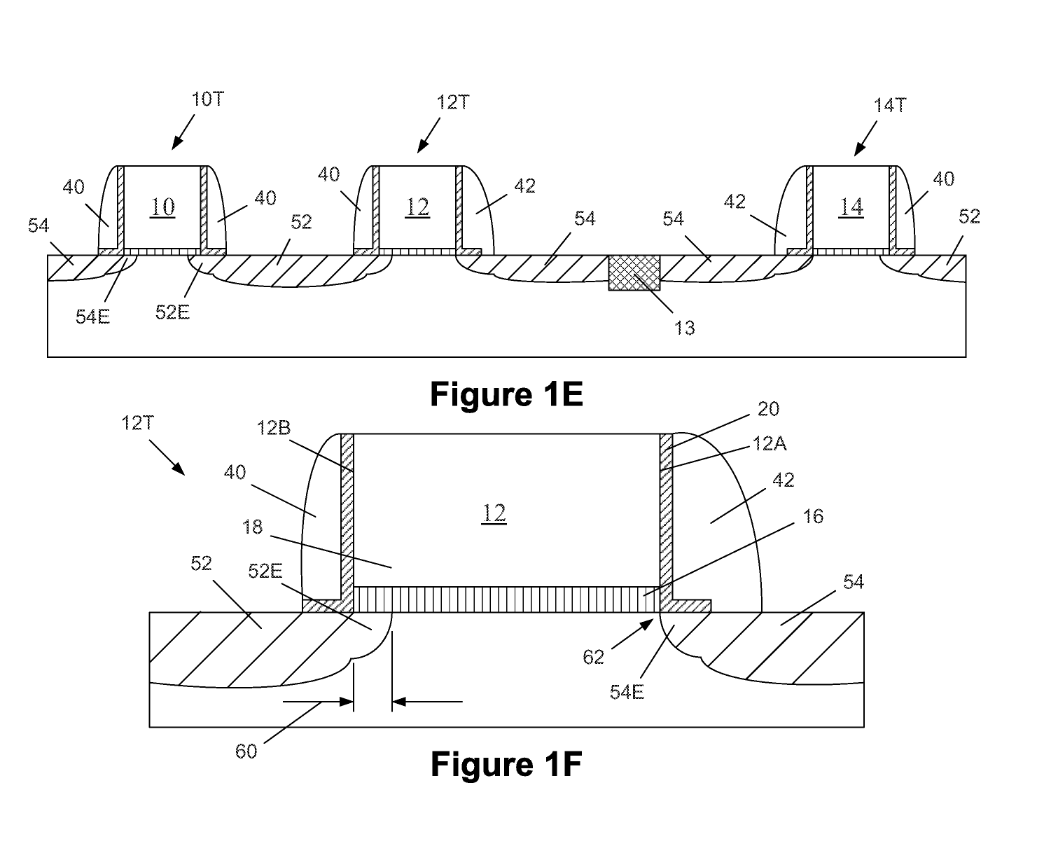

FIG. 1A is a simplified view of an illustrative semiconductor device 100 at an early stage of manufacturing that is formed above a semiconducting substrate 10. In one illustrative embodiment, the semiconducting substrate 10 may be a silicon-on-insulator (SOI) substrate comprised of bulk silicon, a buried insulation layer (commonly referred to as a “BOX” layer) and an active layer (in and above which semiconductor devices are formed), which may also be a silicon material. Of course, the present invention may also be employed when the substrate 10 is made of semiconducting materials other than silicon and/or it may be in another form, such as a bulk silicon configuration. Thus, the terms substrate or semiconductor substrate should be understood to cover all forms of semiconductor structures.

At the point of fabrication depicted in FIG. 2, the semiconductor device 100, e.g., includes neighboring first, second and third gate electrode structures 10, 12, 14. By “neighboring” it is meant that there are no additional gate electrode structures between the gate electrode structures 10 and 12, or between the gate electrode structures 12 and 14. Each of the gate electrode structures include an illustrative gate insulation layer 16, an illustrative gate electrode 18, and each of the gate electrode structures 10, 12, 14, have opposing sidewalls (10A, 10B; 12A, 12B; and 14A, 14B, respectively). The gate insulation layer 16 and the gate electrode 18 may be made of a variety of materials and by using a variety of known techniques. For example, the gate insulation layer 16 may be made of silicon dioxide or a high-k dielectric material (k value greater than 10). The gate electrode 18 may also be made from a variety of materials using a variety of known techniques. For example, the gate electrode 18 may be made of polysilicon, amorphous silicon, a metal, etc. The gate electrode structures 10, 12, 14 may be made using techniques well known to those skilled in the art, such as gate-last or gate-first techniques. In some cases, the gate electrode structures 10, 12, 14 may include a high-k dielectric material (k value greater than 10) and a metal-containing electrode material. An illustrative isolation structure 13, e.g., a shallow trench isolation structure, that is used to separate the ultimate devices, e.g., a transistors, that will include the gate electrode structures 10, 12, 14. For sake of clarity not all of the isolation structures 13 for the device 100 are depicted in the drawings.

Also depicted in FIG. 1A are simplified depictions of an illustrative generally L-shaped liner 20 that is formed on the sidewalls of the gate electrode structures 10, 12, 14. The liner 20 may or may not be present in all applications where the present invention may be employed. The liner 20 may be made using materials and techniques that are well known to those skilled in the art. For example, the liner 20 may be made from silicon nitride or silicon dioxide. Of course, in some applications, one or more additional liners or layers of material may be positioned between the sidewalls of the gate electrode structures 10, 12, 14. Thus, when it is stated herein or in the claims that a sidewall spacer is formed “proximate” one of the gate electrode structures 10, 12, 14, it will be understood to cover situations where such a spacer actually contacts the gate electrode structures 10, 12, 14, as well as a situation where there are one or more intervening layers of material between the spacer and the gate electrode structures 10, 12, 14. In one embodiment, the L-shaped spacer 20 may have a thickness of 5-8 nm, and a width 21 at its base that may be approximately 15-20 nm.

As can be seen in FIG. 1A, the distance 22 between the sidewalls 10A, 12B is less that the distance 24 between the sidewalls 12A, 14B. In one illustrative embodiment, the distance 24 may be approximately 100 nm greater than the distance 22. In one specifically illustrative embodiment, the distance 22 is 150 nm or less, and the distance 24 is approximately 300 nm or greater.

Next, as shown in FIG. 1B, the next step involves performing a non-conformal deposition process to form an uneven layer of spacer material 30 above the gate electrode structures 10, 12, 14. The layer of spacer material 30 may be manufactured by performing standard non-conformal deposition processes. Although the thickness of the non-conformal layer of spacer material 30 is not uniform across the substrate 10 by virtue of the non-conformal deposition process, in general, the thickness of the layer of spacer material 30 in the space between the gate electrode structures 10 and 12 is less than the thickness of the layer of spacer material between the gate electrode structures 12 and 14. In general, depending on the desired width of spacers that will eventually be formed, the overall thickness target for the layer of spacer material 30 may be approximately 10-50 nm. In one particularly illustrative example, the thickness of the layer of spacer material 30, at least in some places between the gate electrodes 10 and 12, may be approximately 15-30 nm, whereas the thickness of the layer of spacer material 30, at least in some places between the gate electrodes 12 and 14 may be approximately 35-50. This thickness differential may be due, at least in part, due to the increased distance 24 between the gate electrodes 12 and 14 as compared to the distance 22 between gate electrodes 10 and 12.

Next, as shown in FIG. 1C, a conventional anisotropic etching process 32 is performed to form a relatively thin spacer 40 and a relative thick spacers 42 proximate the sidewall 12B, 12A, respectively, of the gate electrode structure 12. In the illustrative example depicted in the drawings, the spacers 40, 42 are formed on the liners 20. In one case, the spacers 40, 42 may be made of silicon dioxide and the liner 20 may be made of silicon nitride. In one illustrative example, where the space 22 is approximately 150 nm and the space 24 is approximately 300 nm, the spacer 40 may have a thickness 40W at its base of approximately 15-20 nm, while the spacer 42 may have a thickness 42W at its base of approximately 25-30 nm. In another illustrative example, where the space 22 is approximately 150 nm and the space 24 is approximately 600 nm, the spacer 40 may have a thickness 40W at its base of approximately 15-20 nm, while the spacer 42 may have a thickness 42W at its base of approximately 35 nm. In the depicted example, the spacers proximate the sidewalls 10B, 14A are depicted as the relatively thin spacers 40 due to the relative close proximity of other gate electrode structures (not shown) to the gate electrode structure 10, 14. If a closely spaced gate structure was not present, then the process disclosed herein would result in the formation of the relatively thick spacers 42 proximate the sidewalls 10B and 14A.

FIG. 1D depicts the device 100 at a later stage of manufacture where a source/drain implant process 44 is performed to form doped regions 50 in the substrate 10. The device 100 may have been subjected to earlier implantation processes for forming regions, such as halo regions, extension regions, etc., however those regions are not depicted in the drawings for purposes of clarity. The dopant, dopant dose, and implant energy of the implant process 44 may vary depending on the particular application.

Next, as shown in FIG. 1E, the device 100 is subjected to a heating process to activate the implanted dopants and to repair damage to the lattice structure of the substrate 10. This process results in the formation of a plurality of source regions 52 and drain regions 54 for the illustrative transistor devices 10T, 12T, 14T. The illustrative source regions 52 and drain regions 54 are depicted in the drawings as having illustrative extension region 52E, 54E, although such extension regions may not be required in all applications. The source region 52 between the transistors 10T and 12T may be, for example, a shared source drain region. FIG. 1F is an enlarged view of portions of the transistor 12T having sidewall spacers 40, 42 that are of different size. By virtue of the different size spacers, the location of the implant regions 50, and the resulting location of the extension of the implanted dopant material under the gate electrode 18 may be controlled so as to enhance the performance of the transistor 12T and perhaps at least reduce some of the problems identified in the background section of the application. For example, in one illustrative embodiment, the illustrative extension regions 52E for the source region 52 may extend under the gate electrode 18 by a distance 60 that 2-5 nm, whereas the drain region 54 may not extend under the gate electrode 18 at all, or to any significant degree as indicate in the area 62. In the depicted example the drain region 62 does not extend under the gate electrode 18 at all in the area 62. In this illustrative example, the overlap between the gate electrode 18 and the source region 52 provides the desired good connection between the source region 52 and the channel region of the device, while the elimination or reduction of the amount by which the gate electrode 18 overlaps the drain region 54 may reduce the overall parasitic capacitance of the device which may improve dynamic device performance.

Thus, using the methodologies disclosed herein, the amount to which the source region 52 and/or the drain region 54 extend under the gate electrode 18 can be controlled by performing a non-conformal deposition process to deposit the spacer material. The disclosed examples herein did not involve use of separate masks and separate implant processes to form the illustrative source region 52 and the drain region 54. However, if desired such separate doping steps could be taken while still employing the methods disclosed herein.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

1. A method, comprising:
forming a gate electrode structure above a semiconducting substrate;
performing a non-conformal deposition process to deposit a layer of spacer material above said gate electrode structure; and
performing an anisotropic etching process on said layer of spacer material to define a first sidewall spacer proximate a first side of said gate electrode structure and a second sidewall spacer proximate a second side of said gate electrode structure, said second side being opposite said first side, wherein said first and second sidewall spacers have different widths.

2. The method of claim 1, wherein said second sidewall spacer is wider than said first sidewall spacer.

3. The method of claim 2, further comprising performing a source/drain implant process to form a source region in said substrate proximate said first sidewall spacer and to form a drain region in said substrate proximate said second sidewall spacer.

4. The method of claim 1, wherein said second sidewall spacer is at least 10 nm wider than said first sidewall spacer.

5. The method of claim 1, wherein said second sidewall spacer has a width of at least 25 nm and said first sidewall spacer has a width of less than 20 nm.

6. The method of claim 1, further comprising forming a liner material layer on at least said first and second sidewalls of said gate electrode structure prior to depositing said layer of spacer material.

7. The method of claim 6, wherein said liner material layer is comprised of silicon nitride and said layer of spacer material is comprised of silicon.

8. The method of claim 6 wherein said liner layer has a generally L-shaped configuration.

9. A method of forming a semiconductor device comprising neighboring first, second and third gate electrode structures positioned above a semiconducting substrate, said second gate electrode structure being positioned laterally between said first and third gate electrode structures, each of said gate electrode structures having sidewalls, the method comprising:
forming at least said neighboring first, second and third gate electrode structures above said semiconducting substrate such that a space between the nearest sidewalls of said second and third gate electrode structures is at least 100 nm greater than a space between the nearest sidewalls of said first and second gate electrode structures;
performing a non-conformal deposition process to deposit a layer of spacer material above at least said first, second and third gate electrode structures; and
performing an anisotropic etching process on said layer of spacer material to define a first sidewall spacer proximate a first side of said second gate electrode structure and a second sidewall spacer proximate a second side of said second gate electrode structure, said second side being opposite said first side, wherein said first and second sidewall spacers have different widths.

10. The method of claim 9, wherein said space between said nearest sidewalls of said neighboring second and third gate electrode structures is at least 300 nm.

11. The method of claim 10, wherein said space between said nearest sidewalls of said neighboring first and second gate electrode structures is 150 nm or less.

12. The method of claim 9, wherein said second sidewall spacer is wider than said first sidewall spacer.

13. The method of claim 12, further comprising performing a source/drain implant process to form a source region in said substrate proximate said first sidewall spacer and to form a drain region in said substrate proximate said second sidewall spacer of said second gate electrode structure.

14. The method of claim 9, wherein said second sidewall spacer is at least 10 nm wider than said first sidewall spacer.

15. The method of claim 9, wherein said second sidewall spacer has a width of at least 25 nm and said first sidewall spacer has a width of less than 20 nm.

16. The method of claim 9, further comprising forming a liner material layer on at least the sidewalls of said neighboring first, second and third gate electrode structures prior to depositing said layer of spacer material.

17. The method of claim 1, wherein performing said non-conformal deposition process comprises depositing said layer of spacer material having a first layer thickness proximate said first side of said gate electrode structure and a second layer thickness proximate said second side of said gate electrode structure that is different than said first layer thickness.

18. The method of claim 1, wherein performing said non-conformal deposition process comprises depositing said layer of spacer material having a first layer thickness proximate said first side of said second gate electrode structure and a second layer thickness proximate said second side of said second gate electrode structure that is different than said first layer thickness.
